(19) United States
(12) Patent Application Publication
(10) Pub. No.: US 2018/0047711 A1
(43) Pub. Date: Feb. 15, 2018

(54) ELECTRONIC STACK STRUCTURE HAVING PASSIVE ELEMENTS AND METHOD FOR FABRICATING THE SAME

(71) Applicant: Siliconware Precision Industries Co., Ltd., Taichung City (TW)

(72) Inventors: Chih-Hsien Chiu, Taichung City (TW); Chi-Liang Shih, Taichung City (TW); Jia-Huei Hung, Taichung City (TW); Chia-Yang Chen, Taichung City (TW); Yueh-Chiung Chang, Taichung City (TW)

(21) Appl. No.: 15/352,942

(22) Filed: Nov. 16, 2016

(30) Foreign Application Priority Data
Aug. 9, 2016 (TW) 105125272

(51) Int. Cl. H01L 25/10; H01L 23/538; H01L 23/00; H01L 25/00

(52) U.S. Cl. CPC H01L 25/105; H01L 25/50; H01L 23/5385; H01L 24/16; H01L 2225/1035; H01L 2225/1058; H01L 2225/107; H01L 2225/1088; H01L 2924/19105; H01L 2924/19041; H01L 2924/19042; H01L 2924/19043; H01L 2224/16227

(57) ABSTRACT

An electronic stack structure is provided, including a first substrate, a second substrate stacked on the first substrate through a plurality of passive elements, and an electronic element disposed on at least one of the first substrate and the second substrate. As such, the distance between the first substrate and the second substrate is defined by the height and size of the passive elements. The present disclosure further provides a method for fabricating the electronic stack structure.

### BACKGROUND

### Technical Field

The present disclosure relates to stack structures, and, more particularly, to an electronic stack structure and a method for fabricating the same.

### Description of Related Art

Along with the rapid development of portable electronic products, related products have been developed towards the trend of high density and miniaturization. Accordingly, package on package (PoP) technologies are developed in semiconductor packaging industries to meet the requirements of high density and miniaturization.

FIG. 1 is a schematic cross-sectional view of a conventional PoP structure 1. Referring to FIG. 1, the PoP structure 1 has: a first substrate 11 having a first surface 11a and a second surface 11b opposite to the first surface 11a; a first semiconductor chip 10 disposed in a flip-chip manner on the first surface11aof the first substrate 11; a plurality of solder posts 13 disposed on conductive pads 111 of the first surface 11a of the first substrate 11; a first encapsulant 14 formed on the first surface 11a of the first substrate 11 to encapsulate the first semiconductor chip 10 and the solder posts 13; a plurality of solder balls 114 disposed on conductive pads 112 of the second surface 11b of the first substrate 11; a second substrate 12 stacked on the first substrate 11 through the solder posts 13; a plurality of second semiconductor chips 15a and 15b wire-bonded to the second substrate 12; and a second encapsulant 16 formed on the second substrate 12 to encapsulate the second semiconductor chips 15a, 15b.

In the conventional PoP structure 1, the solder posts 13 are used as supporting and electrical connection elements between the first substrate 11 and the second substrate 12. However, as the I/O count increases, if the size of the package does not change accordingly, the pitch between the solder posts 13 must be reduced. As such, solder bridging may occur between the solder posts 13, thereby reducing the product yield and reliability and making it impossible for the PoP structure to be applied in more sophisticated fine-pitch products.

Further, after a reflow process, the solder posts 13 may have significant differences in size and height from one another. That is, it is not easy to control the size variation of the solder balls 13. As such, defects may occur to solder joints, and result in a poor electrical connection quality. For example, during the reflow process, the solder posts 13 likely collapse and deform under pressure of the second substrate 12. Therefore, solder bridging likely occurs between adjacent solder posts 13, thereby reducing the electrical connection quality. Besides, the solder posts 13 arranged in a grid array may have a poor coplanarity. Consequently, uneven stresses may be applied on the solder joints, thus likely leading to a tilted bonding between the first substrate 11 and the second substrate 12 and even causing an offset of the solder joints.

Furthermore, if the solder posts 13 are replaced by copper posts, the problem of tilted bonding may be overcome. However, the copper posts incur a high cost and is not cost-effective.

Since the solder posts 13 consume spaces of the first substrate 11 and the second substrate 11, it becomes difficult to increase the number of passive elements for the first substrate 11 and the second substrate 11. Therefore, the PoP structure 1 cannot meet the requirement of high performance. In order to increase the number of the chips or passive elements on the first substrate 11 and the second substrate 12, the area of the first substrate 11 and the second substrate 12 must be increased, thus hindering miniaturization of the PoP structure 1.

Also, grounding portions of the passive elements (not shown) on the first substrate 11 or the second substrate 12 need to be connected to a grounding portion of the system through the solder posts 13. Such a long transmission path degrades the electrical characteristic of the PoP structure 1.

Therefore, there is a need to provide an electronic stack structure and a fabrication method thereof so as to overcome the above-described drawbacks.

### SUMMARY

In view of the above-described drawbacks, the present disclosure provides an electronic stack structure, which comprises: a first substrate; a second substrate stacked on the first substrate through a plurality of passive elements; and an electronic element disposed on at least one of the first substrate and the second substrate.

The present disclosure further provides a method for fabricating an electronic stack structure, which comprises: providing a first substrate; and stacking a second substrate on the first substrate through a plurality of passive elements with an electronic element disposed on at least one of the first substrate and the second substrate.

In an embodiment, the electronic element is disposed on at least one of the first substrate and the second substrate through a plurality of conductive bumps.

In an embodiment, each of the passive elements is electrically connected to the first substrate and the second substrate.

In an embodiment, the passive elements are free from being electrically connected to the first substrate and the second substrate.

In an embodiment, at least one of the passive elements is disposed at a corner of the first substrate.

In an embodiment, an encapsulant is formed between the first substrate and the second substrate and encapsulates the passive elements.

Therefore, by stacking the second substrate on the first substrate through the passive elements, the distance between the second substrate and the first substrate is fixed. Compared with the prior art, the present disclosure dispenses with a reflow process of solder posts. Therefore, by maintaining the height and size of the passive elements, the present disclosure overcomes the conventional drawbacks of poor electrical connection quality, poor coplanarity and tilted bonding. Hence, the present disclosure improves the product yield and eliminates the need of high-cost copper posts.

Further, as the passive elements are used as supporting members, the present disclosure can increase the number of the passive elements without the need to increase the area of the first substrate and the second substrate, thereby allowing the overall structure to meet the requirements of high performance and miniaturization.

Furthermore, when the passive elements are used as supporting members, grounding portions of the passive elements can be connected to a grounding portion of the system through a short path. Therefore, the electronic stack structure achieves a preferred electrical characteristic.

### BRIEF DESCRIPTION OF DRAWINGS

FIG. 1 is a schematic cross-sectional view of a conventional PoP structure;

FIGS. 2A to 2C are schematic cross-sectional views showing a method for fabricating an electronic stack structure according to the present disclosure;

FIGS. 3A to 3G are schematic upper views showing various aspects of the electronic stack structure of FIG. 2A (with the electronic elements omitted); and

FIGS. 4A to 4C are schematic cross-sectional views showing other embodiments of the electronic stack structure according to the present disclosure.

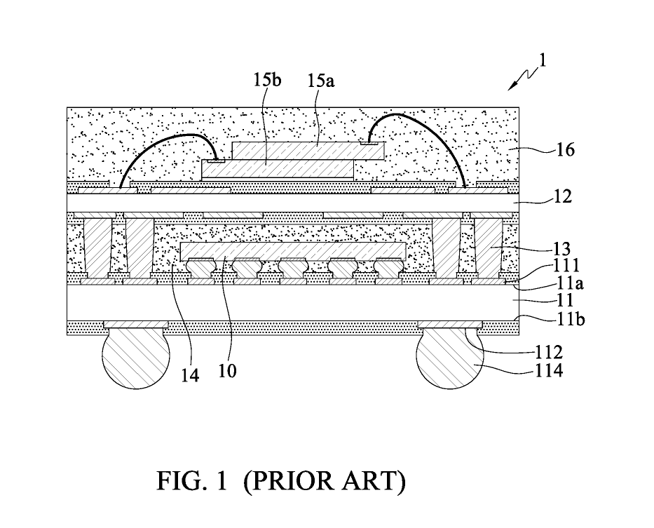

### DETAILED DESCRIPTION OF EMBODIMENTS

The following illustrative embodiments are provided to illustrate the disclosure of the present disclosure, these and other advantages and effects can be apparent to those in the art after reading this specification.

It should be noted that all the drawings are not intended to limit the present disclosure. Various modifications and variations can be made without departing from the spirit of the present disclosure. Further, terms such as “upper”, “lower”, “a” etc. are merely for illustrative purposes and should not be construed to limit the scope of the present disclosure.

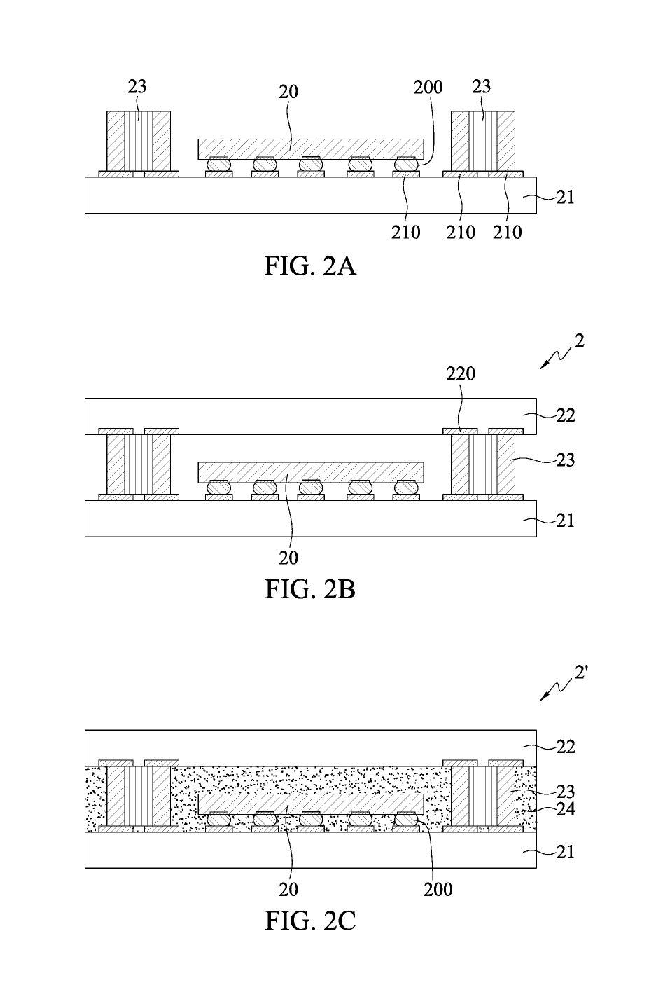

FIGS. 2A to 2C are schematic cross-sectional views showing a method for fabricating an electronic stack structure according to the present disclosure.

Referring to FIG. 2A, a first substrate 21 is provided, and at least a first electronic element 20 and a plurality of passive elements 23 are disposed on the first substrate 21.

In an embodiment, the first substrate 21 is a circuit board having a plurality of circuit layers 210.

The first electronic element 20 is an active element such as a semiconductor chip, a passive element, such as a resistor, a capacitor or an inductor, or a combination thereof. For example, the first electronic element 20 is disposed in a flip-chip manner on the circuit layer 210 of an upper side of the first substrate 21 through a plurality of conductive bumps 200. The conductive bumps 200 are, for example, made of a solder material. Alternatively, the first electronic element 20 can be electrically connected to the circuit layer 210 of the upper side of the first substrate 21 through wire bonding.

Each of the passive elements 23 is, for example, a resistor, a capacitor or an inductor. The passive element 23 can be, or be not electrically connected to the first substrate 21. For example, the passive element 23 is a decoupling capacitor.

Referring to FIG. 2B, a second substrate 22 is bonded to the passive elements 23 so as to be stacked on the first substrate 21 through the passive elements 23, thereby forming an electronic stack structure 2.

In an embodiment, the second substrate 22 is, for example, a silicon interposer, a circuit board or a package. Each of the passive elements 23 can be, or be not electrically connected to the second substrate 22 (a circuit layer 220 of the second substrate 22). For example, the passive element 23 can be a dummy electronic element that only serves as a supporting member and is not electrically connected to the first substrate 21 or the second substrate 22.

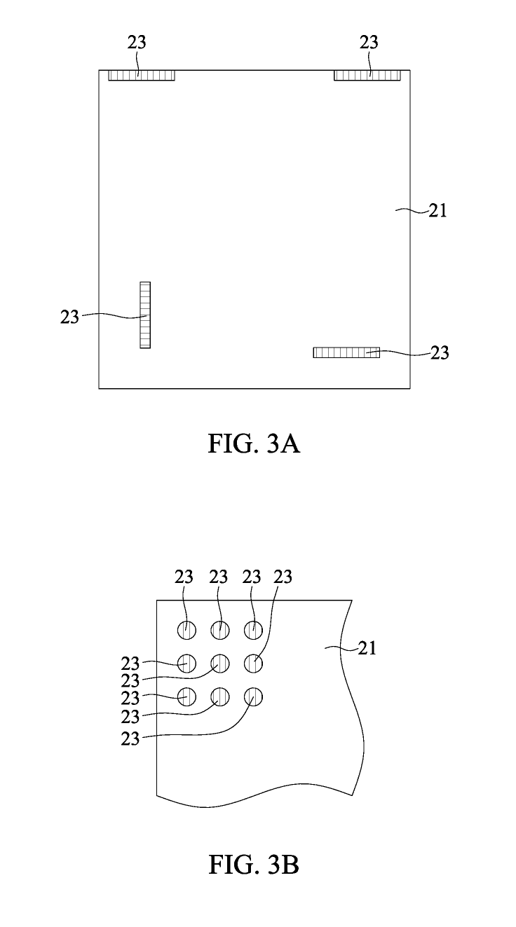

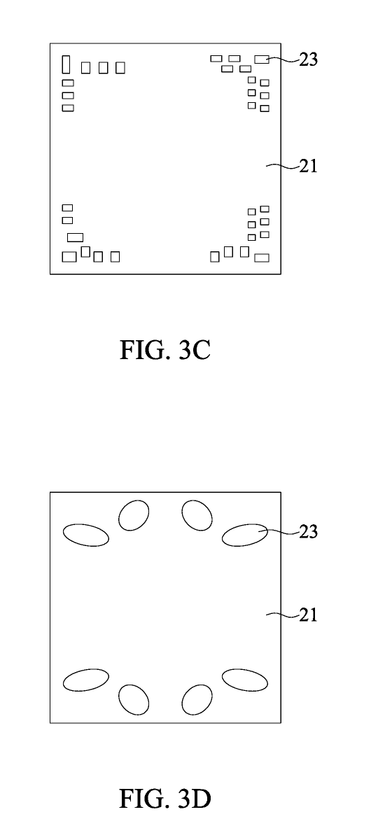

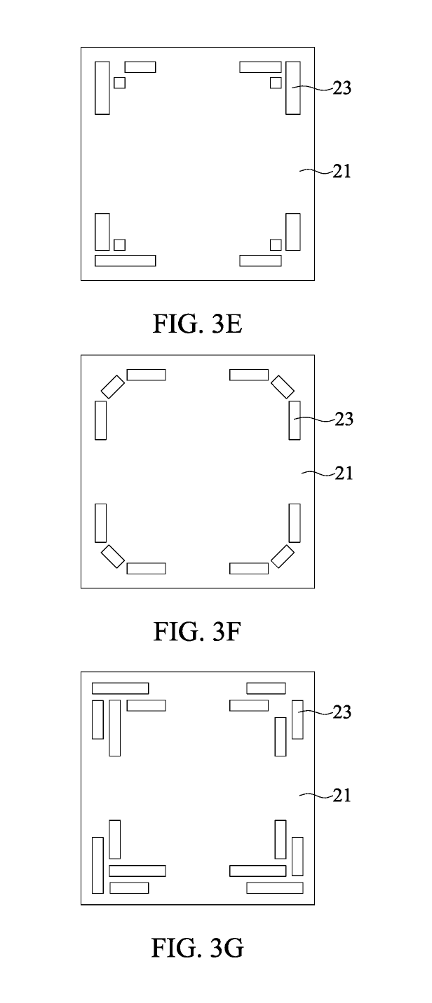

The passive elements 23 can be arranged according to the practical need. Referring to FIG. 3A, the passive elements 23 are arranged according to the weight of the second substrate 22. In particular, the passive elements 23 are arranged at a corner of the first substrate 21 or at a portion of the first substrate 21 that has an unevenly distributed weight (for example, at quarter positions of the substrate). Alternatively, referring to FIGS. 3B to 3G, the passive elements 23 can be arranged according to stress distribution of the electronic stack structure 2. In particular, a plurality of passive elements 23 are disposed at corners of the first substrate 21. That is, stresses concentrate at the corners of the electronic stack structure 2, and, therefore, the passive elements 23 are disposed at the corners to achieve a stress balance and reduce warping of the electronic stack structure 2.

Referring to FIG. 2C, an encapsulant 24 is formed between the upper side of the first substrate 21 and a lower side of the second substrate 22 to encapsulate the first electronic element 20, the passive elements 23 and the conductive bumps 200.

In an embodiment, a plurality of solder balls (not shown) are disposed on the circuit layer of a lower side of the first substrate 21 for bonding with an electronic structure such as a circuit board.

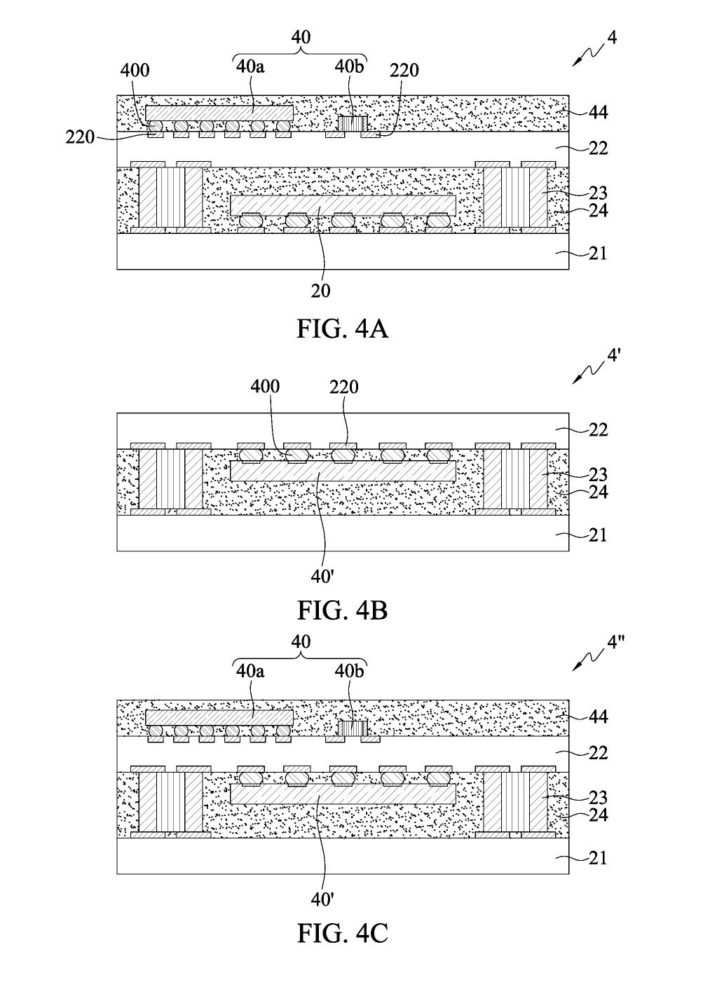

In an embodiment, referring to an electronic stack structure 4 of FIG. 4A, a plurality of second electronic elements 40 are disposed on an upper side of the second substrate 22, and an encapsulant 44 is formed on the upper side of the second substrate 22 to encapsulate the second electronic elements 40. Each of the second electronic elements 40 is an active element 40a such as a semiconductor chip, a passive element 40b, such as a resistor, a capacitor or an inductor, or a combination thereof. For example, the active element 40a is disposed in a flip-chip manner on the circuit layer 220 of the upper side of the second substrate 22 through a plurality of conductive bumps 400, and the conductive bumps 400 are made of a solder material. Alternatively, the active element 40a can be electrically connected to the second substrate 22 through wire bonding.

In another embodiment, referring to an electronic stack structure 4′ of FIG. 4B, a second electronic element 40′ is disposed on the circuit layer 220 of the lower side of the second substrate 22 through a plurality of conductive bumps 400. In fabrication, the second electronic element 40′ is disposed on the lower side of the second substrate 22 first, and then the second substrate 22 with the second electronic element 40′ is disposed on the passive elements 23.

In a further embodiment, an electronic stack structure 4″ of FIG. 4C is achieved by a combination of arrangement of the second electronic elements 40, 40′ of FIGS. 4A and 4B.

In addition to the passive elements 23, supporting members, such as solder posts, copper core balls or other conductive elements can be provided between the first substrate 21 and the second substrate 22 and electrically connected (or not electrically connected) to the first substrate 21 or the second substrate 22.

Further, the passive elements 23 can be disposed on the lower surface of the second substrate 22 first, and then the second substrate 22 is disposed on the first substrate 21 through the passive elements 23. Furthermore, electronic elements (for example, the first electronic element 20 and the second electronic elements 40) can be optionally disposed on the first substrate 21 and/or the second substrate 22.

Therefore, the passive elements 23 serve as supporting and electrical connection elements between the first substrate 21 and the second substrate 22. As such, if the I/O count increases and the pitch between the passive elements 23 is reduced, while the size of the package does not change, bridging will not occur between the passive elements 23, thereby increasing the product yield and reliability and allowing the electronic stack structure 2, 2′, 4, 4′, 4″ to be applied in more sophisticated fine-pitch products.

In an embodiment, the second substrate 22 is directly bonded with the passive elements 23 and a reflow process of solder posts is dispensed with. Therefore, the height and size of the passive elements 23 can be maintained and the distance between the second substrate 22 and the first substrate 21 is fixed. Consequently, the electronic stack structures 2, 2′, 4, 4′, 4″ achieve a good electrical connection quality, a good coplanarity and a good stress balance, and hence a tilted bonding is avoided from occurring between the first substrate 21 and the second substrate 22 so as to prevent a joint offset from occurring.

Further, since the distance between the second substrate 22 and the first substrate 21 is fixed, even if additional solder posts are further disposed between the second substrate 22 and the first substrate 21 and a reflow process is performed on the solder posts, the height and size of the solder posts can still be controlled. Therefore, after the reflow process is performed on the solder posts, solder joints formed from the solder posts have a good electrical connection quality, and a grid array arranged by the solder posts has a good coplanarity, and a good stress balance is maintained, such that a tilted bonding between the first substrate 21 and the second substrate 22 and a joint offset problem are avoided.

Furthermore, as the passive elements 23 are used as supporting members, more passive elements can be disposed on the first substrate 21 and the second substrate 22, without the need to increase the area of the first substrate 21 and the second substrate 22, thus allowing the electronic stack structure 2, 2′, 4, 4′, 4″ to meet the requirements of high performance and miniaturization.

When the passive elements 23 are used as supporting members, grounding portions of the passive elements 23 can be connected to the first electronic element 20 and a grounding portion of the system through a shortest path (i.e., a path directly connecting the circuit layer 210 of the first substrate 21 with the circuit layer 220 of the second substrate 22). Compared with the conventional long path through solder posts, the electronic stack structures 2, 2′, 4, 4′ and 4″ achieve a preferred electrical characteristic.

The present disclosure further provides an electronic stack structure 2, 2′, 4, 4′, 4″ which has: a first substrate 21; a plurality of passive elements 23 disposed on the first substrate 21; a second substrate 22 disposed on the passive elements 23; a first electronic element 20 disposed on the first substrate 21; a plurality of second electronic elements 40, 40′ disposed on the second substrate 22; and an encapsulant 24 formed between the first substrate 21 and the second substrate 22.

The second substrate 22 is stacked on the first substrate 21 through the passive elements 23.

The encapsulant 24 encapsulates the passive elements 23.

In an embodiment, the first electronic element 20 is disposed on the first substrate 21 through a plurality of conductive bumps 200.

In an embodiment, the second electronic elements 40, 40′ are disposed on the second substrate 22 through a plurality of conductive bumps 400.

In an embodiment, the passive elements 23 are electrically connected to the first substrate 21 and/or the second substrate 22.

In an embodiment, the passive elements 23 are not electrically connected to the first substrate 21 or the second substrate 22.

In an embodiment, the passive elements 23 are disposed at a corner of the first substrate 21.

According to the present disclosure, by stacking the second substrate on the first substrate through the passive elements, the distance between the second substrate and the first substrate is fixed. Therefore, the present disclosure achieves a good electrical connection quality, a good coplanarity and a good stress balance, and hence avoids tilted bonding.

Further, as the passive elements are used as supporting members, the present disclosure can increase the number of the passive elements without the need to increase the area of the first substrate and the second substrate, thus allowing the electronic stack structure to meet the requirements of high performance and miniaturization.

Furthermore, when the passive elements are used as supporting members, grounding portions of the passive elements can be connected to a grounding portion of the system through a shortest path. Therefore, the electronic stack structure achieves a preferred electrical characteristic.

The above-described descriptions of the detailed embodiments are only to illustrate the implementation according to the present disclosure, and it is not to limit the scope of the present disclosure. Accordingly, all modifications and variations completed by those with ordinary skill in the art should fall within the scope of present disclosure defined by the appended claims.

1: An electronic stack structure, comprising:
a first substrate;
a second substrate stacked on the first substrate through a plurality of passive elements, wherein the plurality of passive elements are disposed at one corner of the first substrate; and
an electronic element disposed on at least one of the first substrate and the second substrate.

2: The electronic stack structure of claim 1, wherein the electronic element is disposed on the first substrate through a plurality of conductive bumps.

3: The electronic stack structure of claim 1, wherein the electronic element is disposed on the second substrate through a plurality of conductive bumps.

4: The electronic stack structure of claim 1, wherein each of the passive elements is electrically connected to at least one of the first substrate and the second substrate.

5: The electronic stack structure of claim 1, wherein the passive elements are free from being electrically connected to the first substrate and the second substrate.

6. (canceled)

7: The electronic stack structure of claim 1, wherein at least one of the passive elements is disposed on a portion of the first substrate having an unevenly distributed weight.

8: The electronic stack structure of claim 1, further comprising an encapsulant formed between the first substrate and the second substrate and encapsulating the passive elements.

9: A method for fabricating an electronic stack structure, comprising:
providing a first substrate; and
stacking a second substrate on the first substrate through a plurality of passive elements with an electronic element disposed on at least one of the first substrate and the second substrate, wherein the plurality of passive elements are disposed at one corner of the first substrate.

10: The method of claim 9, wherein the electronic element is disposed on the first substrate through a plurality of conductive bumps.

11: The method of claim 9, wherein the electronic element is disposed on the second substrate through a plurality of conductive bumps.

12: The method of claim 9, wherein each of the passive elements is electrically connected to at least one of the first substrate and the second substrate.

13: The method of claim 9, wherein the passive elements are free from being electrically connected to the first substrate and the second substrate.

14. (canceled)

15: The method claim 9, wherein at least one of the passive elements is disposed on a portion of the first substrate having an unevenly distributed weight.

16: The method of claim 9, further comprising forming between the first substrate and the second substrate an encapsulant encapsulating the passive elements.
